(19) United States
(12) Patent Application Publication
(10) Pub. No.: US 2002/0177260 A1
(43) Pub. Date: Nov. 28, 2002

(54) Semiconductor device and method of fabricating the same

(76) Inventor: Koichi Matsumoto, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/057,495

(22) Filed: Jan. 25, 2002

(30) Foreign Application Priority Data
Jan. 29, 2001 (JP) P2001-020745

(51) Int. Cl. H01L 27/01; H01L 21/00; H01L 21/84

(52) U.S. Cl. 438/154; 257/347

(57) ABSTRACT

The present invention provides a highly integrated semiconductor device including C-MOS transistors fabricated on a SOI substrate and a method of fabricating such semiconductor device. The semiconductor device comprises a plurality of first conductivity type impurity diffused regions formed in a semiconductor layer on a SOI substrate, a second conductivity type body region, a plurality of second conductivity type impurity diffused regions, a first conductivity type body region, a junction surface of one of the first conductivity type impurity diffused regions and one of the second conductivity type impurity diffused regions, a conductive (silicide) layer formed on at least one of the first conductivity type impurity diffused regions and one of the second conductivity type impurity diffused regions including the junction surface and a gate insulation film and the gate electrodes stacked on the first and second conductivity type body regions.

### CROSS REFERENCES TO RELATED APPLICATIONS

The present invention claims priority to priority document no. 2001-020745 filed in Japan on Jan. 29, 2001, and incorporated by reference herein.

### BACKGROUND OF THE INVENTION

1. Field of the Invention

The present invention relates generally to a semiconductor device having FETs (Field Effect Transistors) fabricated on a SOI (Silicon On Insulator or Semiconductor On Insulator) substrate and a method of fabricating the same, and more specifically to a semiconductor device having FD (Fully Depleted) type MOS-FETs (Metal Oxide Semiconductor-Field Effect Transistors) and a method of fabricating the same.

2. Description of the Related Art

Transistors fabricated on a SOI substrate feature shorter delay time due to significantly reduced junction capacitance as compared to transistors fabricated on a bulk substrate. Additionally, reduced junction capacitance contributes to reduce power required to charge and discharge load capacitance which is reduced by the reduced junction capacitance. As a result of improved quality and reduced production cost of SOI substrates in recent years, mass production of LSIs (Large Scale Integrated circuits) using SOI substrates is in progress.

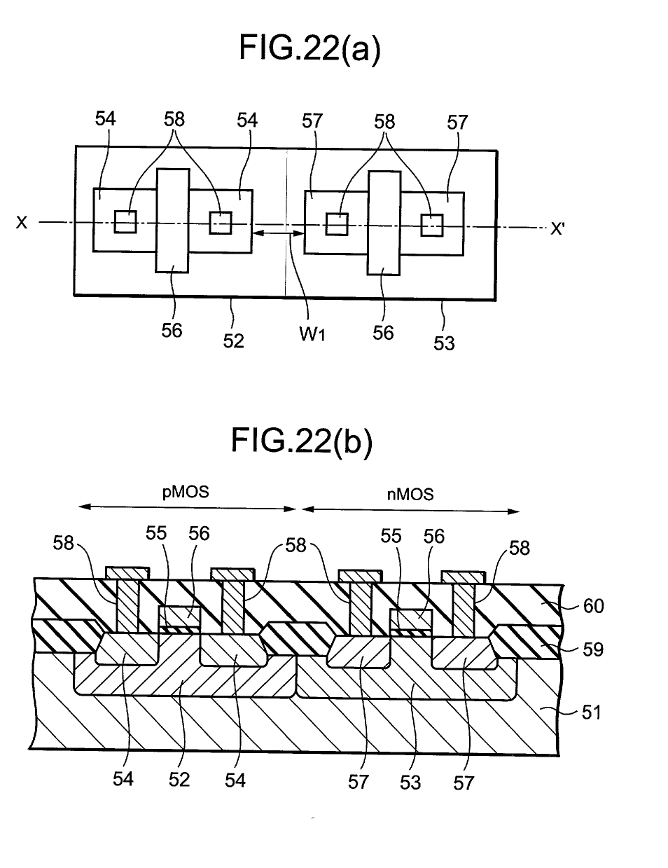

Illustrated in FIG. 22(a) is a layout drawing of C-MOS (Complementary MOS) transistors fabricated on a bulk substrate. FIG. 22(b) is a cross section view along the line X-X′ in FIG. 22(a). As illustrated in FIG. 22(b), a low concentration n-type impurity diffused layer (n-well) 52 and a low concentration p-type impurity diffused layer (p-well) 53 are formed in a surface area of a silicon substrate 51. P-MOS transistors each including a p-type source/drain region 54, a gate insulation film 55 and a gate electrode 56 are formed in the n-well 52. On the other hand, n-MOS transistors each including n-type source/drain region 57, a gate insulation film 55 and a gate electrode 56 are formed in the p-well 53. In general, the n-well 52 is connected to a power supply while the p-well 53 is connected to ground. The n-well 52 and the p-well 53 of the C-MOS transistors in FIGS. 22(a), 22(b) are formed in the depth of, e.g., 3 μm, thereby developing relatively large junction capacitance between the wells 52, 53 and the silicon substrate 51.

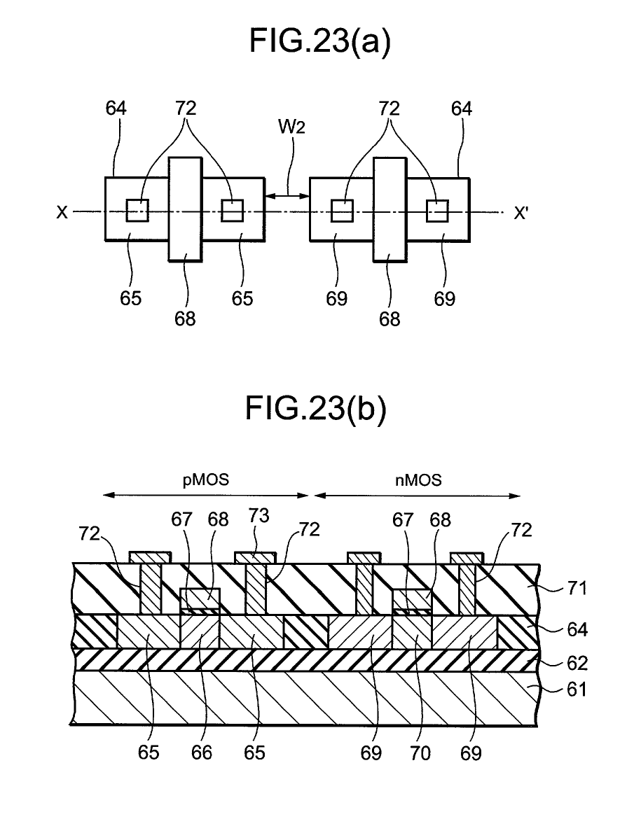

On the other hand, illustrated in FIG. 23(a) is a layout of fabricating C-MOS transistors on a SOI substrate. FIG. 23(b) is a cross section view along the line X-X′ in FIG. 23(a). As illustrated in FIG. 23(b), a silicon layer is formed on the silicon substrate 61 by way of a buried oxide film 62, thereby constituting a SOI substrate. Formed in the silicon layer is a device isolation region 64 such as, e.g., LOCOS (Local Oxidation of Silicon), STI (Shallow Trench Isolation), etc. The device isolation region 64 reaches the buried oxide film 62, thereby completely isolating devices by the device isolation region 64 and the oxide film 62.

Formed in the silicon layer for p-MOS transistor portion are p-type source/drain regions 65 and a p-type body region sandwiched there-between. A gate insulation film 67 and a gate electrode 68 are formed on the p-type body region 66. On the other hand, formed in the silicon layer for n-MOS transistor portion are n-type source/drain regions 69 and an n-type body region 60 being sandwiched there-between. A gate insulation film 67 and a gate electrode 68 are formed on an n-type body region 70.

According to the C-MOS transistors as illustrated in FIGS. 23(a), 23(b), the p-MOS and n-MOS transistors are completely isolated by the insulation film, thereby suppressing a soft error and preventing latch-up problem that is inherent to C-MOS transistors. As a result, it solves the latch-up problem preventing miniaturization of C-MOS transistors, thereby realizing highly integrated LSIs.

In case of fabricating C-MOS transistors on a silicon substrate, n-MOS and p-MOS transistors are required to have a relatively large separation width W1 as illustrated in FIG. 22(a), to secure withstanding voltage between the wells. In contrast, in case of fabricating C-MOS transistors on a SOI substrate, a separation width W2 as shown in FIG. 23(a) can be smaller than the separation width W1 between the p-MOS and n-MOS transistors. This means that the SOI substrate is advantageous for high density LSIs.

MOS transistors fabricated on SOI substrates are classified into fully depleted (FD) and partially depleted (PD) types. Such fully depleted type MOS transistors feature a thin (e.g., 50 nm or less) silicon layer on the buried oxide film, thereby operating in always depleted condition in the body region between the source and drain regions.

On the other hand, such partially depleted MOS transistors feature a thick (e.g., 100 nm or thicker) silicon layer on the buried oxide film. As a result, they operate in the condition having non-depleted zone at the bottom portion of the body region, i.e., the depletion layer below the channel does not reach the buried oxide film.

Such partially depleted MOS transistors have the characteristic to exhibit higher withstanding voltage between source and drain than fully depleted MOS transistors. On the other hand, fully depleted MOS transistors exhibit significantly reduced junction capacitance, excellent sub-threshold characteristic and excellent switching performance.

In partially depleted MOS transistors, holes developed near the drain region are accumulated in the body region and bias the body potential. This results in increased drain current to disturb current-voltage characteristic (kink effect). In order to prevent such kink effect, it is necessary to clamp the potential of the body region (body potential). That is, it is necessary to form a body terminal at one portion of the active region.

In case of the fully depleted n-MOS transistors, a potential barrier for holes between the source and the body is low enough not to cause the kink effect, thereby eliminating the need for a body terminal for clamping the body potential. As integration of semiconductor devices become higher, there are strong needs for reducing a layout area. There are many cases where reduction of the layout area of semiconductor devices is limited by the geometry of wirings or by the separation width of p-MOS and n-MOS transistors.

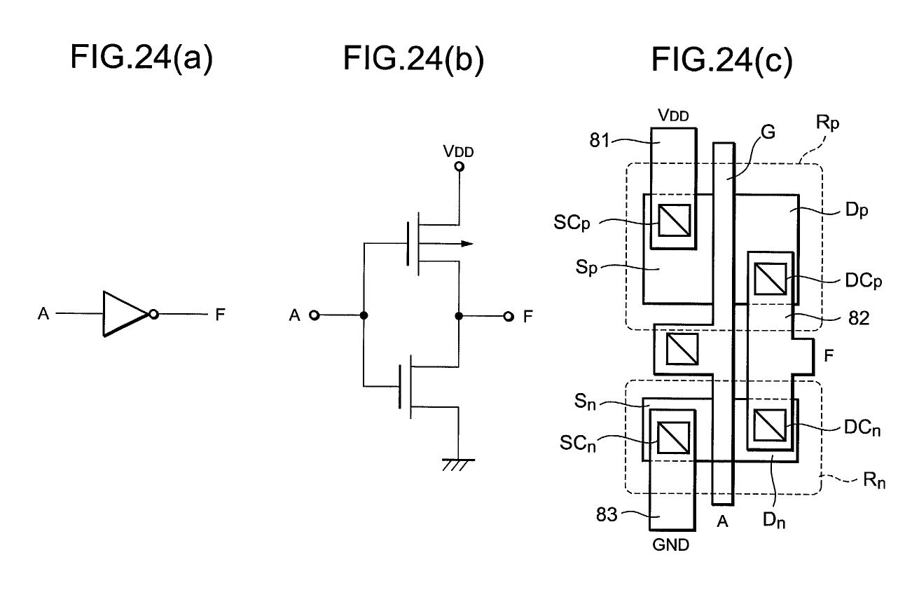

Illustrated in FIGS. 24(a), (b), (c) is a C-MOS inverter as an example of circuits to be fabricated on a SOI substrate. A truth table of the C-MOS inverter is given in the following Table 1:

TABLE 1

| input A | output F |
|---|---|
| 1 | 0 |
| 0 | 1 |

FIG. 24(a) is a logic symbol of the C-MOS inverter, FIG. 24(b) is a circuit diagram of the C-MOS inverter and FIG. 24(c) is a layout drawing of a conventional C-MOS inverter. As shown in FIG. 24(b), the n-MOS transistor acts as a driver MOS transistor while the p-MOS transistor acts as a load MOS transistor. The gates and the drains of the both p-MOS and n-MOS transistors are coupled together and define input and output terminals, respectively. The source of the p-MOS transistor is connected to the power supply voltage VDD. On the other hand, the source of the n-MOS transistor is returned to ground. The C-MOS inverter operates in such a manner that either one of the transistors becomes conductive in the normal condition depending on the input signal A, thereby consuming essentially no power because no DC current path exists. The power is consumed only in a switching transient period.

As illustrated in FIG. 24(c), wiring 81 is connected between the source region Sp of the p-MOS transistor and the power supply VDD, wiring 82 is connected between the drain region Dp of the p-MOS transistor and the drain region Dn of the n-MOS transistor, and wiring 83 is connected between the source region Sn and ground. For example, aluminum wiring is used for the wirings 81˜83. The source region Sp of the p-MOS transistor is connected to the wiring 81 by way of the source contact SCp. The drain region Dp of the p-MOS transistor is connected to the wiring 82 by way of the drain contact DCp. The drain region Dn of the n-MOS transistor is connected to the wiring 82 by way of the drain contact DCn. The source region Sn of the n-MOS transistor is connected to the wiring 83 by way of the source contact SCn.

The input signal A as shown in FIGS. 24(a) and (b) is applied to the gate line G as shown in FIG. 24(c) while the output signal F in FIGS. 24(a) and (b) is applied to the wiring 82 in FIG. 24(c).

Represented by Rp in FIG. 24(c) is a resist pattern acting as a mask for impurity ion implantation in the p-MOS transistor portion. It is this resist pattern to be used for forming p-type source/drain regions Sp and Dp. On the other hand, represented by Rn is a resist pattern acting as a mask for impurity ion implantation in the n-MOS transistor portion. It is this resist pattern to be used for forming the n-type source/drain regions Sn and Dn.

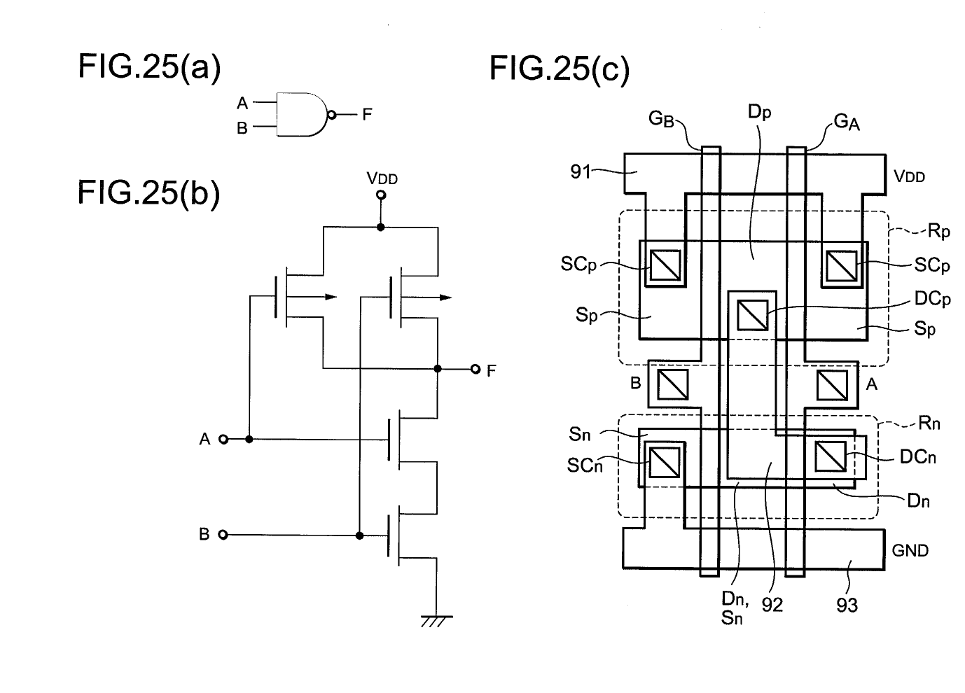

Illustrated in FIGS. 25(a), (b), (c) is a 2-input NAND gate which is another example of a circuit to be fabricated on a SOI substrate. A table 2 is a truth table of the 2-input NAND gate.

TABLE 2

| input A | input B | output F |
|---|---|---|
| 1 | 1 | 0 |
| 1 | 0 | 1 |
| 0 | 1 | 1 |
| 0 | 0 | 1 |

FIG. 25(a) shows a logic symbol of the 2-input NAND gate, FIG. 25(b) is a circuit schematic of the 2-input NAND gate and FIG. 25(c) is a layout drawing of a conventional 2-input NAND gate. As shown in FIG. 25(b), a pair of p-MOS transistors are connected in parallel and a pair of n-MOS transistors are connected in series. The source potential of the p-MOS transistors is clamped to the power supply voltage VDD. The drains of the p-MOS transistors define the output terminal. The source potential of the n-MOS transistor is grounded and the drain of the n-MOS transistor defines the output terminal. The input signal A is applied to the gate electrodes of one each of the n-MOS and p-MOS transistors. On the other hand, the input signal B is applied to the gates of the other n-MOS and p-MOS transistors.

As illustrated in FIG. 25(c), wiring 91 is connected between the source region Sp of the p-MOS transistor and the voltage source VDD. Wiring 92 is connected between the drain region Dp of the p-MOS transistor and the drain region Dn of the n-MOS transistor. Wiring 93 is connected between the source region Sn of the n-MOS transistor and ground. For example, aluminum (Al) wiring is used as the wirings 91˜93.

The source region Sp of the p-MOS transistors and the wiring 91 are connected together by way of the source contacts SCp. The drain region Dp of the p-MOS transistors and the wiring 92 are connected together by way of the drain contact DCp. The drain region Dn of the n-MOS transistor and the wiring 92 are connected together by way of the drain contact DCn. The source region Sn of the n-MOS transistor and the wiring 93 are connected together by way of the source contact SCn.

The input signal A as shown in FIGS. 25(a) and (b) is applied to the gate line GA in FIG. 25(c). On the other hand, the input signal B as shown in FIGS. 25(a) and (b) is applied to the gate line GB in FIG. 25(c). The output signal F as shown in FIGS. 25(a) and (b) is derived from the wiring 92 in FIG. 25(c). Represented by Rp in FIG. 25(c) is a resist pattern acting as a mask for impurity ion implantation at the portion of the 2 p-MOS transistors. This resist pattern is used for forming p-type source/drain regions Sp and Dp. On the other hand, represented by Rn in FIG. 25(c) is a resist pattern acting as a mask for impurity ion implantation at the portion of the 2 n-MOS transistors. This resist pattern is used for forming the n-type source/drain regions Sn and Dn.

In the above mentioned conventional semiconductor devices, there are formed device isolation regions of a given width between devices. In case of fabricating C-MOS transistors on a bulk substrate as illustrated in FIGS. 22(a), (b), (c), the device isolation region has a sufficient separation width W1 in order to maintain necessary withstanding voltage. On the other hand, in case of fabricating C-MOS transistors on a SOI substrate, the separation width W2 between devices as shown in FIG. 23 can be reduced as compared to the separation width W1. However, even in this case, the device isolation region 64 of the insulation film is required between p-MOS and n-MOS transistors. Although not shown in these figures, there are cases to form wells below the buried oxide film in the SOI substrate by implanting impurity ion into a silicon substrate. In this particular case, there requires separation width capable of maintaining the well withstanding voltage as is the case of bulk substrate.

Additionally, connections between p-MOS and n-MOS transistors are made by the upper layer wiring 73 by way of the insulation layer 71 on top of the transistors. In case of the fully depleted MOS transistors, the buried oxide layer does exist immediately below the source/drain regions. As a result, if potentials of the impurity diffused regions of n-MOS and p-MOS transistors are equal, there is no need for the device isolation region between them.

According to the layouts of the conventional C-MOS circuits as shown in FIGS. 24(c) and 25(c), wirings for interconnecting p-MOS and n-MOS transistors (i.e., the wiring 82 in FIG. 24(c) and the wiring 93 in FIG. 25(c)) are disposed on the insulation layer, thereby preventing high integration of semiconductor devices and accompanying increased wiring capacitance. Furthermore, there is a need for connecting the drain regions and the upper layer wirings by forming drain contacts DCp and DCn as shown in FIGS. 24(c) and 25(c). In case of forming the drain contacts DCp and DCn, there is a need for providing alignment margin in photolithography process, thereby preventing miniaturization of semiconductor devices.

### SUMMARY OF THE INVENTION

The present invention is directed to solving the aforementioned problems associated with conventional semiconductor devices. It is therefore one aspect of the present invention to provide semiconductor devices including highly integrated C-MOS transistors fabricated on a SOI substrate and a method of fabricating such semiconductor devices.

In order to achieve the above objectives, the semiconductor device according to the present invention comprises a substrate, a buried insulation film in the substrate, a semiconductor layer formed on the buried insulation film, device isolation insulation regions surrounding the semiconductor layer on the buried insulation film, a plurality of first conductivity type impurity diffused regions in the semiconductor layer, a second conductivity type body region formed in the semiconductor layer between the first conductivity type impurity diffused regions, a plurality of second conductivity type impurity diffused regions formed in the semiconductor layer, a first conductivity type body region formed in the semiconductor layer between the second conductivity type impurity diffused regions, a junction surface of one of the first conductivity type impurity diffused regions and one of the second conductivity type impurity diffused regions, a conductive layer formed on one of the first conductivity type impurity diffused regions and one of the second conductivity type impurity regions including the junction surface, a gate insulation film formed on the first conductivity type body region and the second conductivity type body region, and gate electrodes formed on the gate insulation film.

Preferably, the semiconductor layer of the semiconductor device according to the present invention includes silicon and the conduction layer includes a metal silicide layer. Preferably, the semiconductor device according to the present invention further comprises a first wiring for connecting the other one of the first conductivity type impurity diffused regions not contacting the second conductivity type impurity diffused regions and the power supply, and a second wiring for grounding one of the second conductivity type impurity diffused regions not contacting the first conductivity type impurity diffused regions.

Preferably, the semiconductor device according to the present invention includes a pair of first conductivity type impurity diffused regions and a pair of second conductivity type impurity diffused regions. Alternatively, it is preferable that the semiconductor device according to the present invention includes 3 first conductivity type impurity diffused regions and 3 second conductivity type impurity diffused regions, wherein the gate electrodes comprise first gate electrodes formed on one of the first conductivity type body regions and one of the second conductivity type body regions, and second gate electrodes formed on one of the other first conductivity type body regions and one of the other second conductivity type body regions separated from the first gate electrodes. Preferably, the semiconductor device according to the present invention further comprises the conductive layer formed on the surface of the gate electrodes. Preferably, the semiconductor device according to the present invention further comprises side-walls of an insulation film formed on the side surface of the gate electrodes and the conductive layer is formed on the gate electrodes.

Alternatively, it is preferable that the semiconductor device according to the present invention further comprises side-walls of an insulation film formed on the side surface of the gate electrodes, first conductivity type LDD (Lightly Doped Drain) regions formed in the semiconductor layer at the lower portion of the side-walls and the area contacting the second conductivity type body region and containing a first conductivity type impurity of lower concentration than the first conductivity type impurity diffused regions and second conductivity type LDD regions formed in the semiconductor layer at the lower portion of the side-walls and the area contacting the first conductivity type body region and containing the second conductivity type impurity of lower concentration than the second conductivity type impurity diffused regions. Preferably, the semiconductor device according to the present invention further includes the conductive layer formed on the gate electrodes.

Accordingly, the separation width between p-MOS and n-MOS transistors is not required, thereby reducing wiring capacitance and providing a margin in the layout for the upper layer wiring.

Additionally, in order to achieve the above objectives, the method of fabricating semiconductor device according to the present invention comprises the steps of forming a semiconductor layer on a substrate by way of a buried insulation film, forming device isolation insulation regions surrounding the semiconductor layer on the buried insulation film, forming a first conductivity type body region in one part of the semiconductor layer, forming a second conductivity type body region in one part of the semiconductor layer, forming a gate insulation film on the first and second conductivity type body regions, forming gate electrodes on the gate insulation film, forming a plurality of first conductivity type impurity diffused regions on the semiconductor layer by way of the second conductivity type body region, forming a plurality of second conductivity type impurity diffused regions on the semiconductor layer by way of the first conductivity type body region in such a manner that one of the first conductivity type impurity diffused regions and one of the second conductivity type impurity diffused regions contact to provide a junction surface, and forming a conduction layer on at least one of the first conductivity type impurity diffused regions and one of the second conductivity type impurity diffused regions including the junction surface.

Preferably, the method of fabricating semiconductor device according to the present invention includes silicon as the semiconductor layer and the step of forming the conduction layer forms a metal silicide layer. Preferably, the method of fabricating semiconductor device according to the present invention further comprises the steps of forming an insulation film on at least the first conductivity type impurity diffused regions, the second conductivity type impurity diffused regions and the gate electrodes, forming a first wiring for connecting one of the other first conductivity type impurity diffused regions and the power supply, and forming a second wiring on the insulation film for grounding one of the other second conductivity type impurity diffused regions after forming the conduction layer.

Preferably, the method of fabricating semiconductor device according to the present invention features in that the step of forming the first conductivity type impurity diffused regions includes a step of implanting the first conductivity type impurity ion into the semiconductor layer using the gate electrodes as a mask, the step of forming the second conductivity type impurity diffused regions includes a step of implanting second conductivity type impurity ion into the semiconductor layer using the gate electrodes as a mask. Preferably, the method of fabricating semiconductor device according to the present invention features in that the step of forming the conduction layer includes a step of forming the conductive layer on the surface of the gate electrodes.

Preferably, the method of fabricating semiconductor device according to the present invention further comprises the step of forming side-walls of an insulation film on the side surface of the gate electrodes prior to forming the conductive layer, and the step of forming the conductive layer forming the conductive layer on the gate electrodes. The method of fabricating semiconductor device according to the present invention is preferable in that the step of forming the side-walls is carried out after forming the gate electrodes but prior to forming the first and second conductivity type impurity diffused regions. Alternatively, the method of fabricating semiconductor device according to the present invention is preferable in that the step of forming the side-walls is carried out after forming the first and second conductivity type impurity diffused regions.

Preferably, the method of fabricating semiconductor device according to the present invention further comprises the steps of forming a first conductivity type LDD regions by implanting the first conductivity type impurity ion into the semiconductor layer using the gate electrodes as a mask after forming the gate electrodes but before forming the first conductivity type impurity diffused regions, forming a second conductivity type LDD regions by implanting the second conductivity type impurity ion into the semiconductor layer using the gate electrodes as a mask after forming the gate electrodes but before forming the second conductivity type impurity diffused regions, and forming side-walls of an insulation film on the side surface of the gate electrodes after forming the first and second conductivity type LDD regions, wherein the step of forming the first conductivity type impurity diffused regions is carried out by implanting the first conductivity type impurity ion into the semiconductor layer using the side-walls as a mask and the step of forming the second conductivity type impurity diffused regions is carried out by implanting the second conductivity type impurity ion into the semiconductor layer using the side-walls as a mask. Preferably, the step of forming the conduction layer in the method of fabricating semiconductor device according to the present invention is to form the conductive layer on the gate electrodes.

Accordingly, the present invention enables to fabricate highly integrated C-MOS transistors on a SOI substrate. The method of fabricating semiconductor device according to the present invention eliminates separation width between p-MOS and n-MOS transistors, thereby reducing the layout area. Also, elimination of upper layer wiring for connecting p-MOS and n-MOS transistors contributes to reduce wiring capacitance.

BRIEF DESCRIPTION OF THE DRAWINGS

Now, the above and other objectives and resulting advantages will become apparent from the following detailed description of preferred embodiments of the present invention by reference to accompanying drawings, in which:

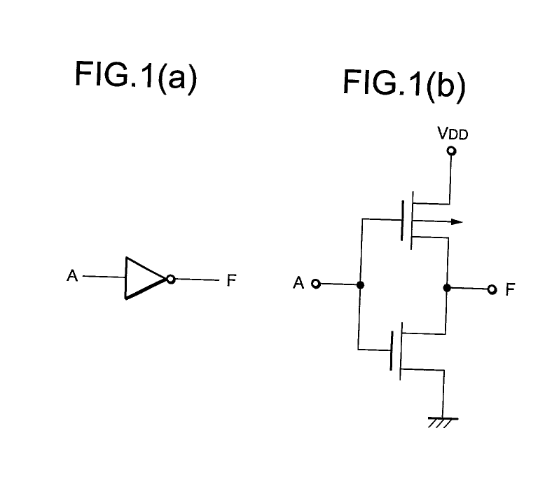

FIGS. 1(a), (b) show a C-MOS transistor according to a first embodiment of the present invention, wherein

FIG. 1(a) is a logic symbol and

FIG. 1(b) is a circuit schematic;

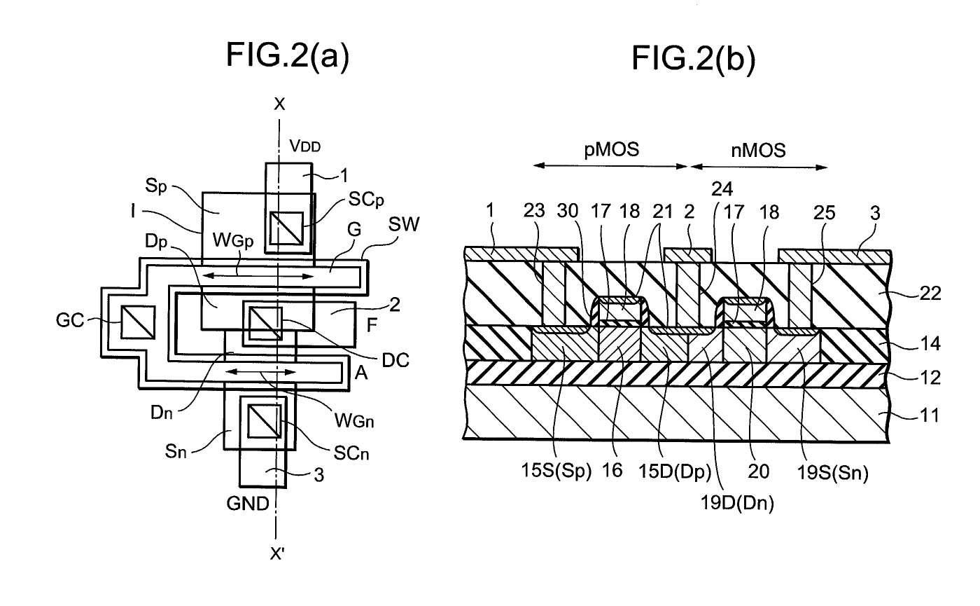

FIGS. 2(a), (b), show a C-MOS inverter according to a first embodiment of the present invention, wherein

FIG. 2(a) is a layout drawing and

FIG. 2(b) is a cross section view along the line X-X′ in FIG. 2(a);

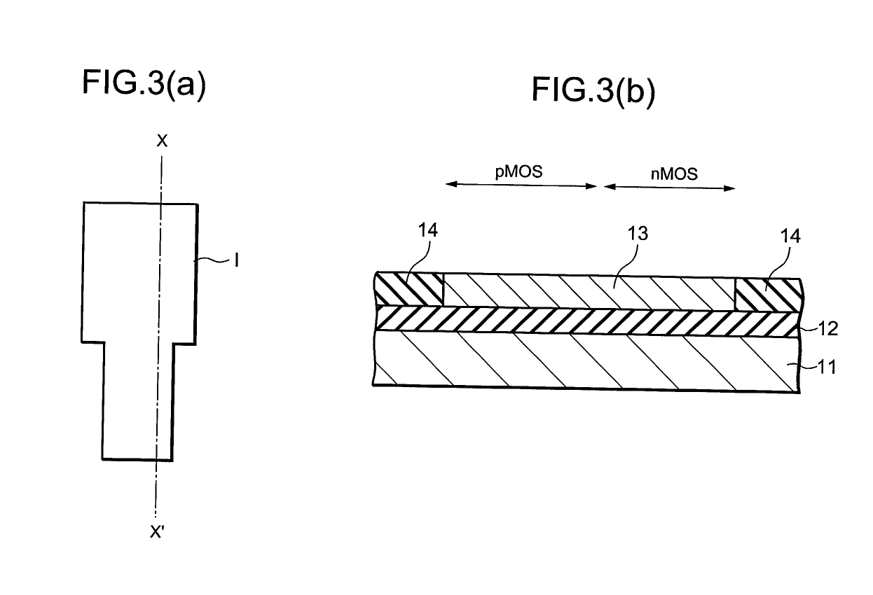

FIGS. 3(a), (b) show a first fabrication step of the C-MOS inverter according to the first embodiment of the present invention, wherein

FIG. 3(a) is a layout drawing and

FIG. 3(b) is a cross section view along the line X-X′ in FIG. 3(a);

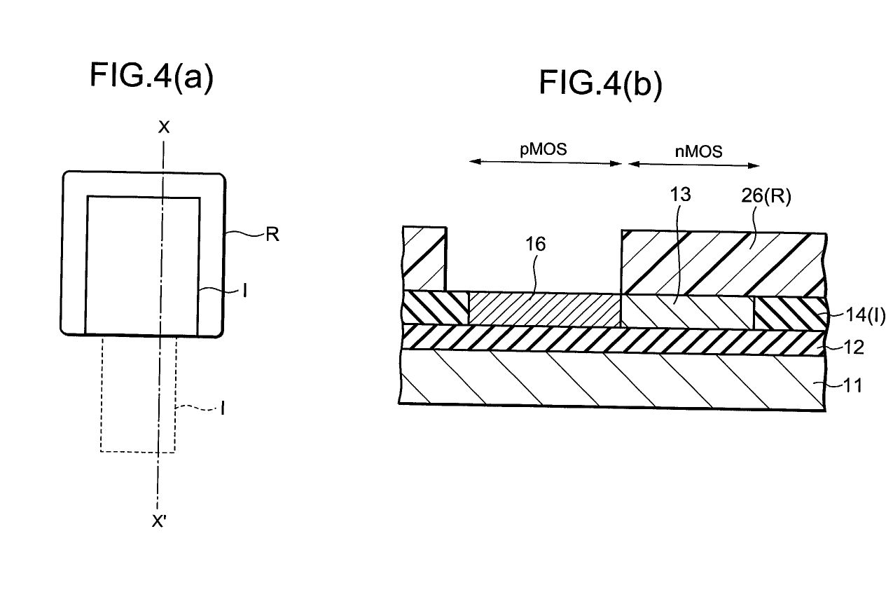

FIGS. 4(a), (b) show a second fabrication step of the C-MOS inverter according to the first embodiment of the present invention, wherein FIG. 4(a) is a layout design and

FIG. 4(b) is a cross section view along the line X-X′ in FIG. 4(a);

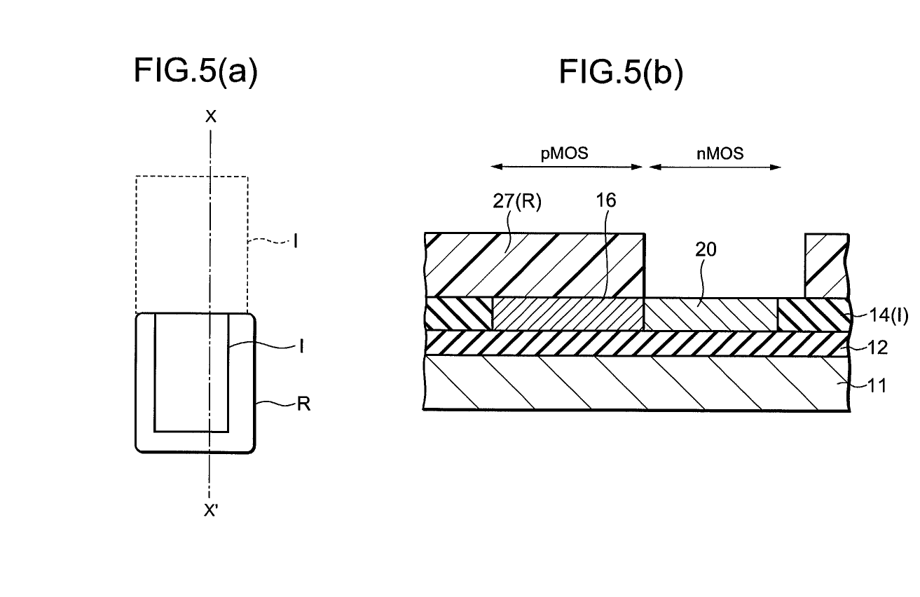

FIGS. 5(a), (b) show a third fabrication step of the C-MOS inverter according to the first embodiment of the present invention, wherein

FIG. 5(a) is a layout design and

FIG. 5(b) is a cross section view along the line X-X′ in FIG. 5(a);

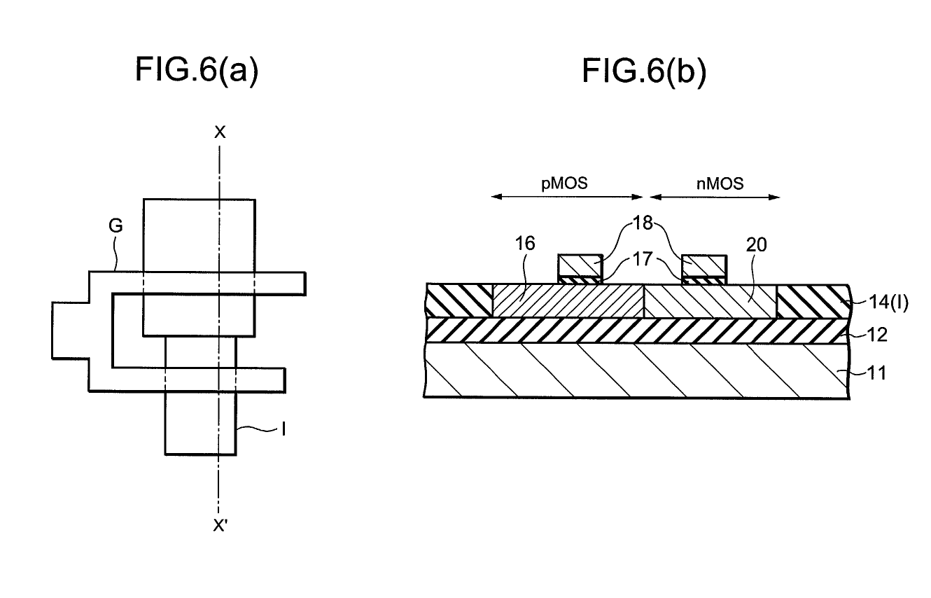

FIGS. 6(a), (b) show a fourth step of fabricating the C-MOS inverter according to the present invention of the present invention, wherein

FIG. 6(a) is a layout drawing and

FIG. 6(b) is a cross section view along the line X-X′ in FIG. 6(a);

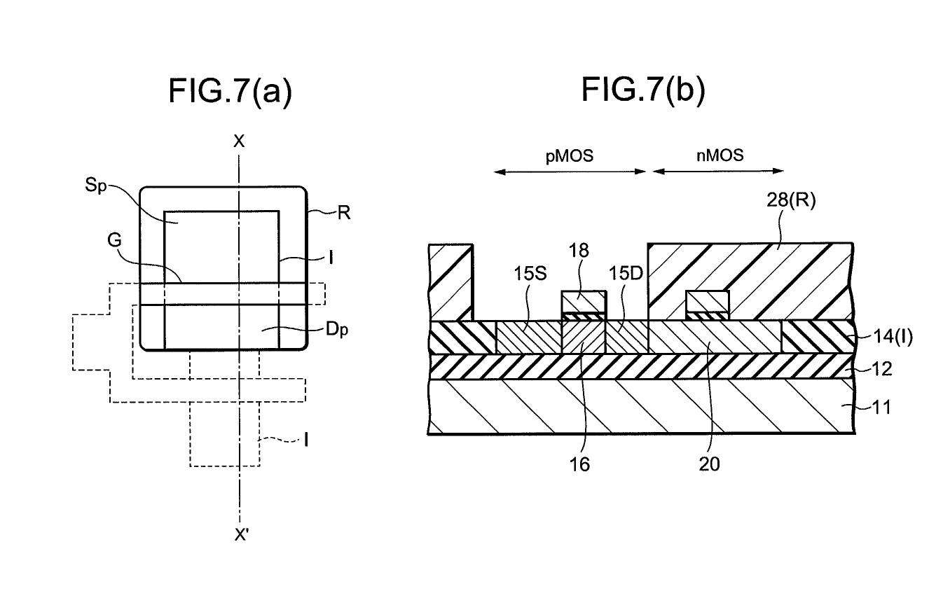

FIGS. 7(a), (b) show a fifth fabrication step of the C-MOS inverter according to the first embodiment of the present invention, wherein

FIG. 7(a) is a layout drawing and

FIG. 7(b) is a cross section view along the line X-X′ in FIG. 7(a);

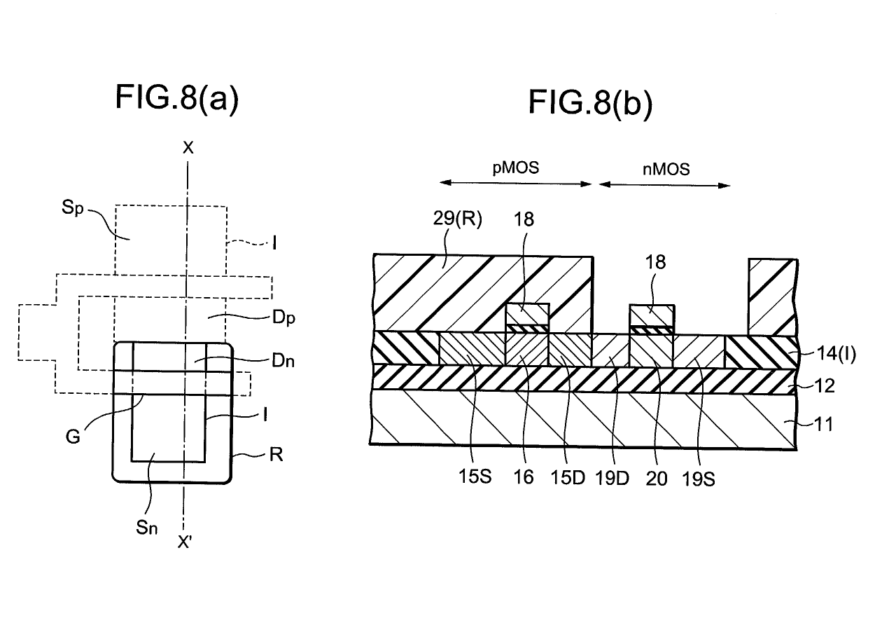

FIGS. 8(a), (b) show a sixth fabrication step of the C-MOS inverter according to the first embodiment of the present invention, wherein

FIG. 8(a) is a layout drawing and FIG. 8(b) is a cross section view along the line X-X′ in FIG. 8(a);

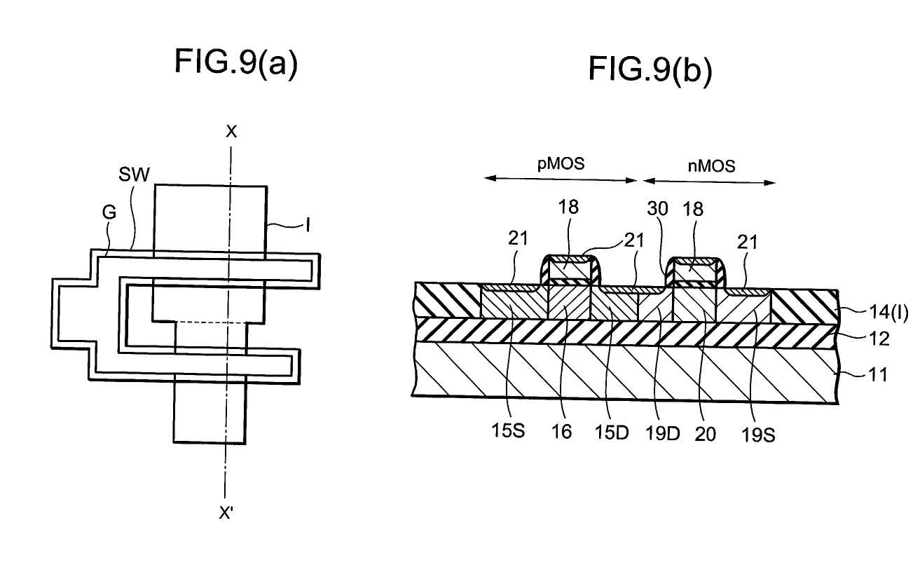

FIGS. 9(a), (b) show a seventh fabrication step of the C-MOS inverter according to the first embodiment of the present invention, wherein

FIG. 9(a) is a layout drawing and

FIG. 9(b) is a cross section view along the line X-X′ in FIG. 9(a);

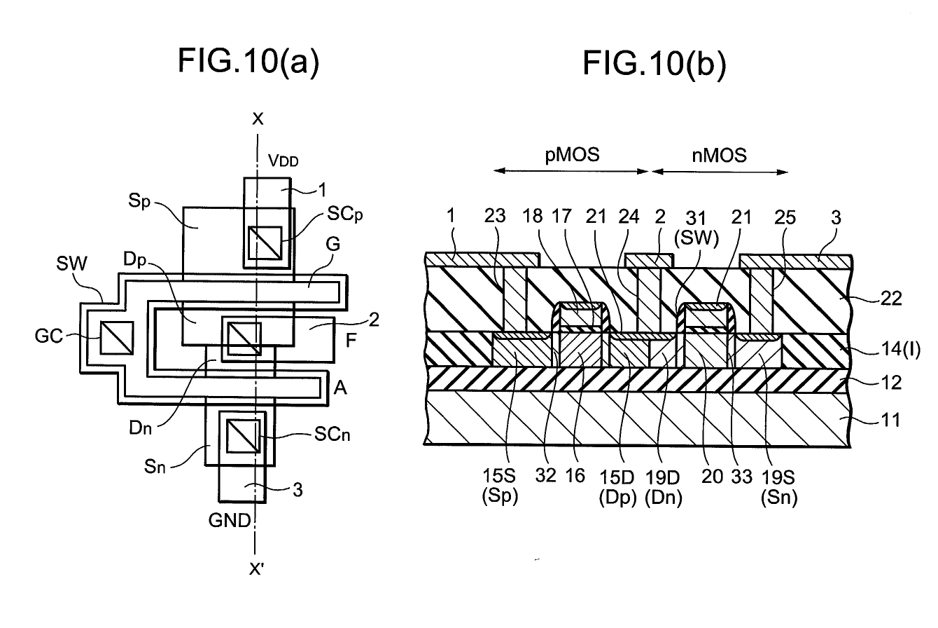

FIGS. 10(a), (b) show a C-MOS inverter according to a second embodiment of the present invention, wherein

FIG. 10(a) is a layout drawing and

FIG. 10(b) is a cross section view along the line X-X′ in FIG. 10(a);

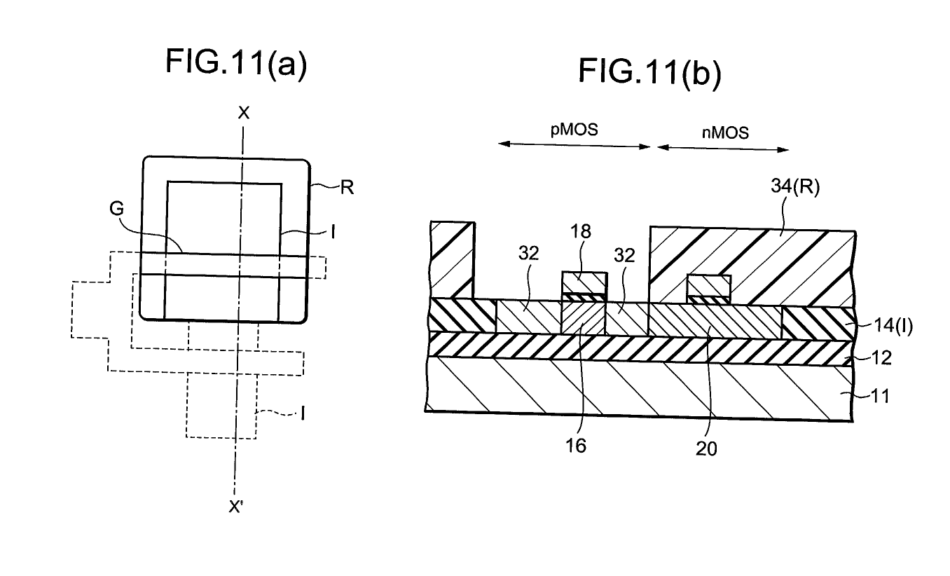

FIGS. 11(a), (b) show a first fabrication step of the C-MOS inverter according to the second embodiment of the present invention, wherein FIG. 11(a) is a layout drawing and

FIG. 11(b) is a cross section view along the line X-X′ in FIG. 11(a);

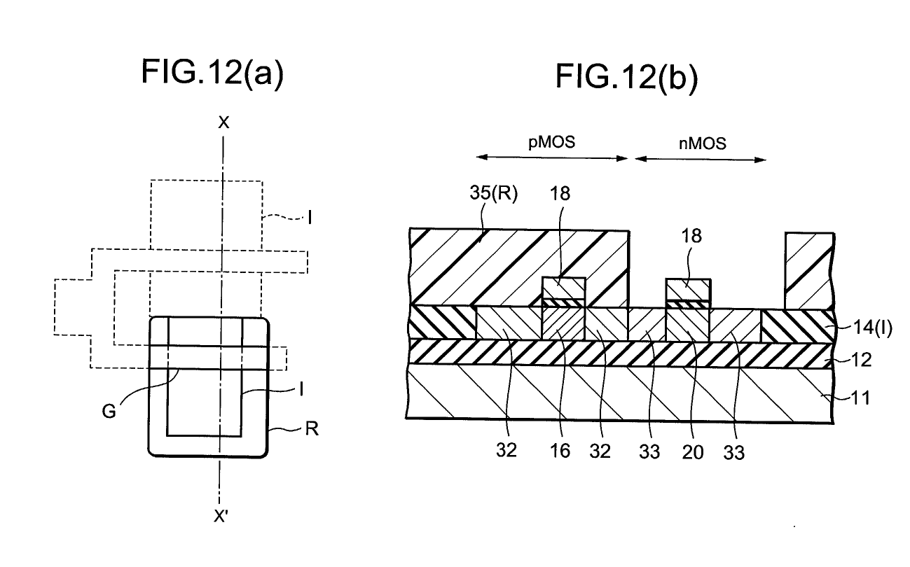

FIGS. 12(a), (b) show a second fabrication step of the C-MOS inverter according to the second embodiment of the present invention, wherein

FIG. 12(a) is a layout drawing and

FIG. 12(b) is a cross section view along the line X-X′ in FIG. 12(a);

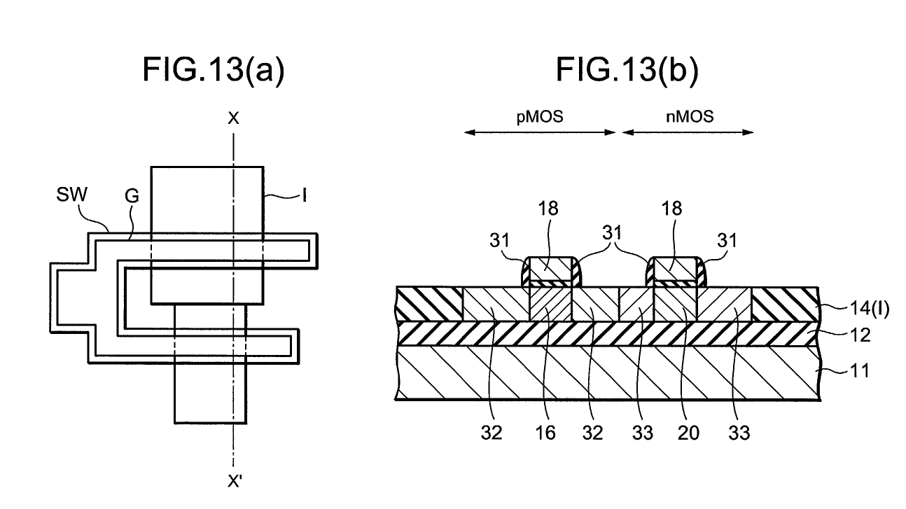

FIGS. 13(a), (b) show a third step of fabrication step according to the second embodiment of the present invention, wherein

FIG. 13(a) is a layout drawing and

FIG. 13(b) is a cross section view along the line X-X′ in FIG. 13(a);

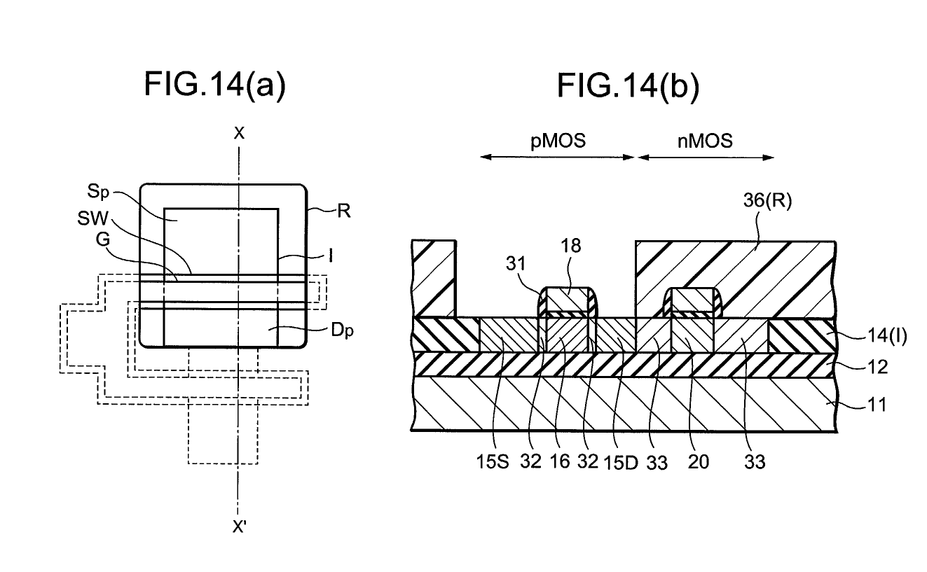

FIGS. 14(a), (b) show a fourth fabrication step of the C-MOS inverter according to the second embodiment of the present invention, wherein

FIG. 14(a) is a layout drawing and

FIG. 14(b) is a cross section view along the line X-X′ in FIG. 14(a);

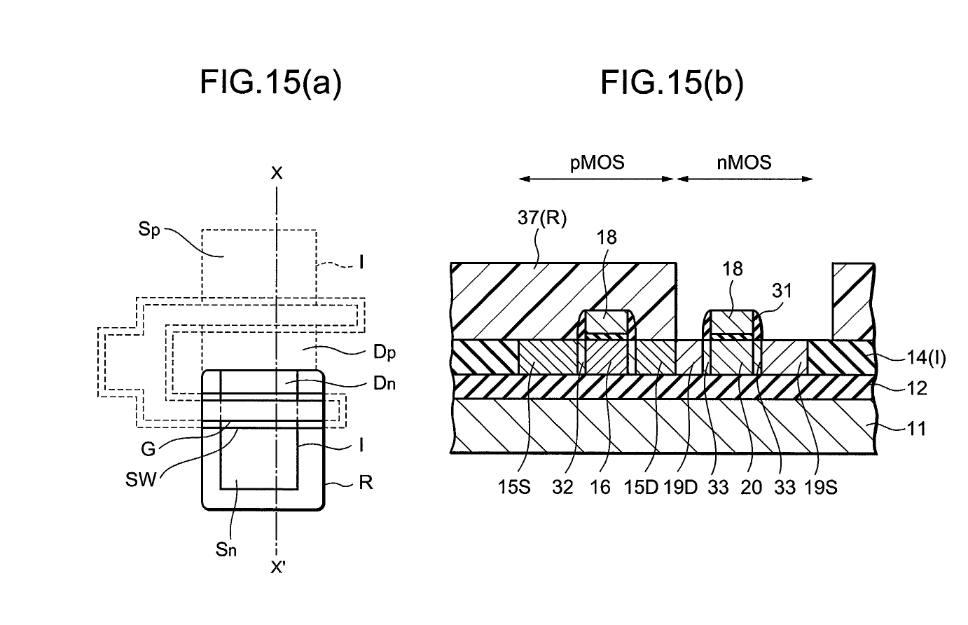

FIGS. 15(a), (b) show a fifth fabrication step of the C-MOS inverter according to the second embodiment of the present invention, wherein

FIG. 15(a) is a layout drawing and

FIG. 15(b) is a cross section view along the line X-X′ in FIG. 15(a);

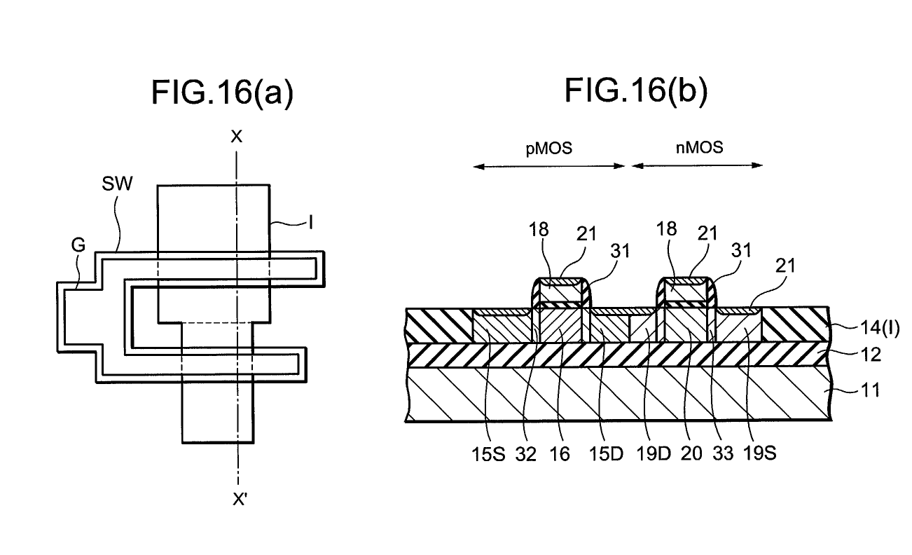

FIGS. 16(a), (b) show a sixth fabrication step of the C-MOS inverter according to the second embodiment of the present invention, wherein

FIG. 16(a) is a layout drawing and

FIG. 16(b) is a cross section view along the line X-X′ in FIG. 16(a);

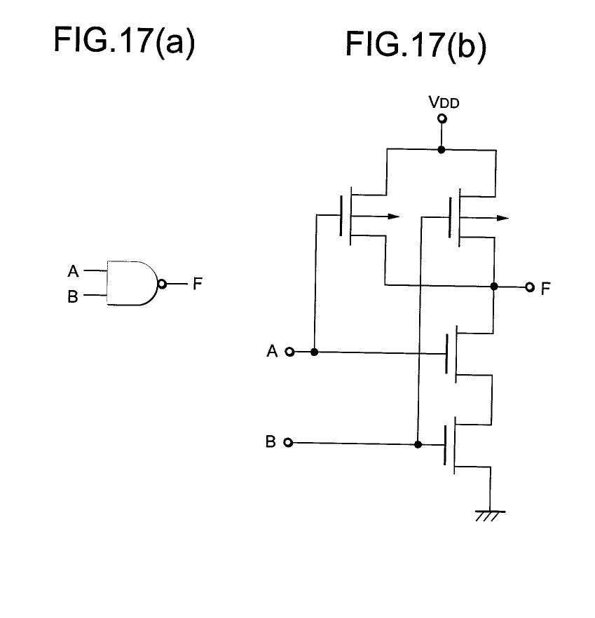

FIGS. 17(a), (b) show a 2-input NAND gate according to a third embodiment of the present invention, wherein

FIG. 17(a) is a logic symbol and

FIG. 17(b) is a circuit schematic;

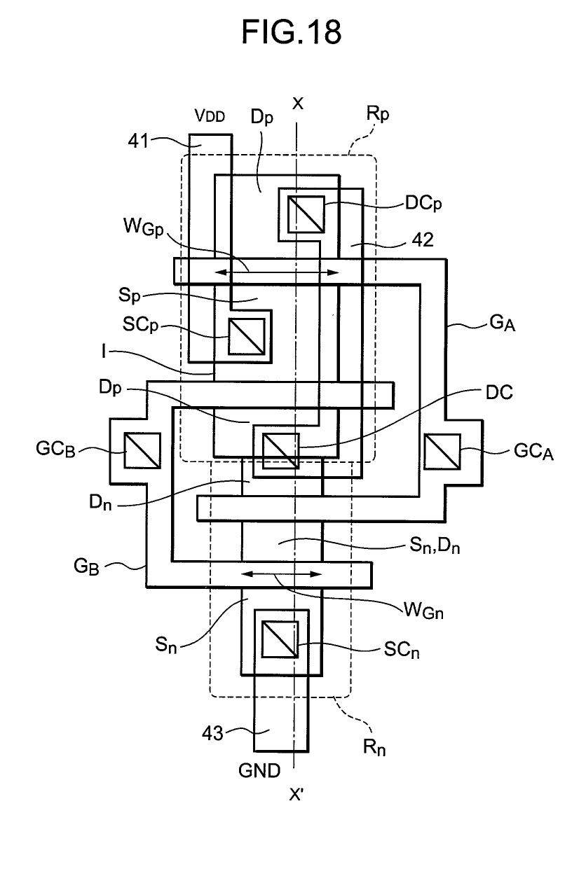

FIG. 18 is a layout drawing of the 2-input NAND gate according to the third embodiment of the present invention;

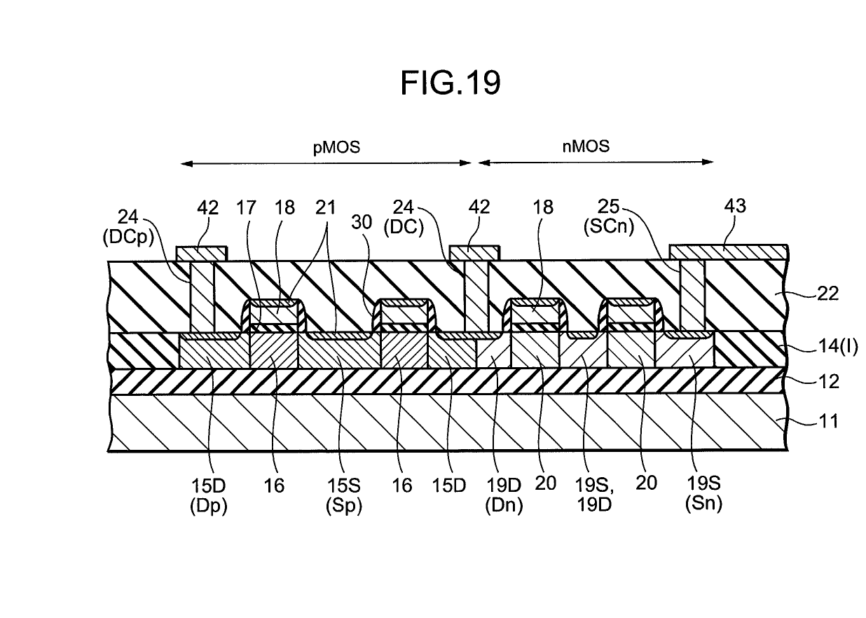

FIG. 19 is a cross section view along the line X-X′ in FIG. 18;

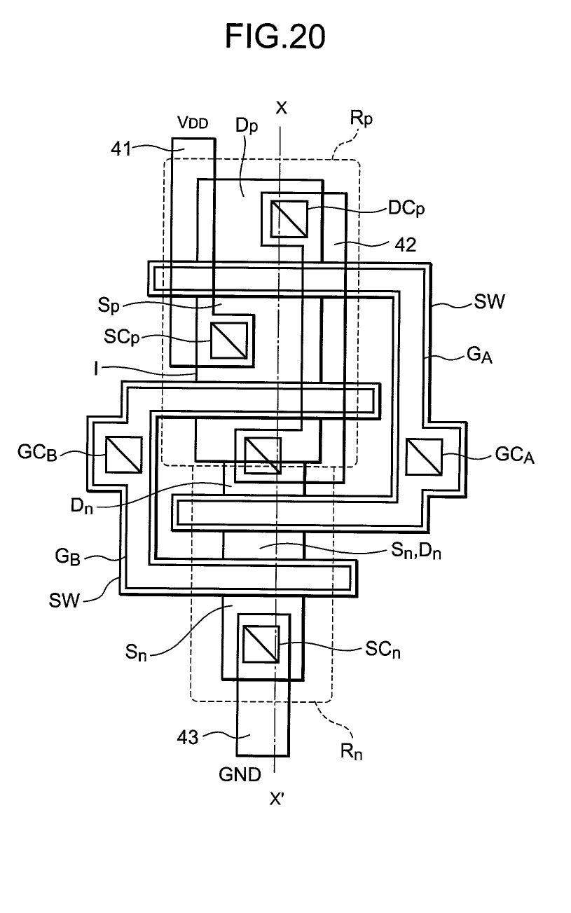

FIG. 20 is a layout drawing of the 2-input NAND gate according to the third embodiment of the present invention;

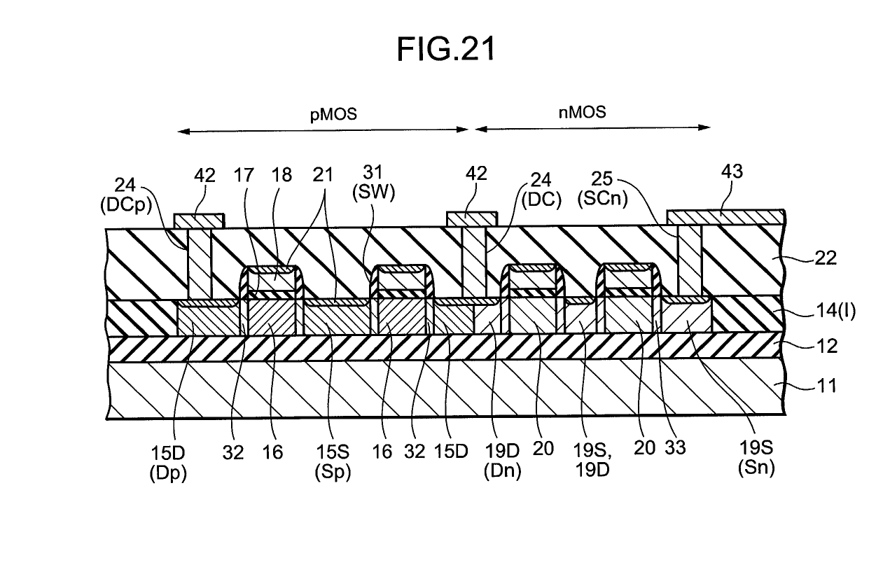

FIG. 21 is a cross section view along the line X-X′ in FIG. 20;

FIGS. 22(a), (b) show a first example of conventional semiconductor devices, wherein

FIG. 22(a) is a layout drawing and

FIG. 22(b) is a cross section view along the line X-X′ in FIG. 22(a);

FIGS. 23(a), (b) show a second example of conventional semiconductor devices, wherein

FIG. 23(a) is a layout drawing and

FIG. 23(b) is a cross section view along the line X-X′ in FIG. 23(a);

FIGS. 24(a), (b), (c) show a conventional C-MOS inverter, wherein

FIG. 24(a) is a logic symbol,

FIG. 24(b) is a circuit schematic and

FIG. 24(c) is a layout drawing; and

FIGS. 25(a), (b), (c) show a conventional 2-input NAND gate, wherein

FIG. 25(a) is a logic symbol,

FIG. 25(b) is a circuit schematic and

FIG. 25(c) is a layout drawing.

### DESCRIPTION OF THE PREFERRED EMBODIMENTS

(First Embodiment)

FIG. 1 illustrates a C-MOS inverter as an example of circuits fabricated on a SOI substrate, wherein FIG. 1(a) is a logic symbol of the C-MOS inverter and FIG. 1(b) is a circuit schematic of the C-MOS inverter. A truth table of the C-MOS inverter is given in the following Table 3:

TABLE 3

| input A | output F |
|---|---|
| 1 | 0 |
| 0 | 1 |

As shown in FIG. 1(b), n-MOS and p-MOS transistors act as a driver MOS transistor and a load MOS transistor, respectively. Gates and drains of the p-MOS and n-MOS transistors are coupled together to define an input terminal and an output terminal, respectively. A source of the p-MOS transistor is clamed to the power supply voltage VDD while a source of the n-MOS transistor is connected to ground potential. Under the normal condition of the C-MOS inverter, either one of the transistors becomes conductive depending on the input signal A. Since no DC current path is established, the C-MOS inverter consumes essentially no power except in switching transient periods.

Illustrated in FIG. 2(a) is a layout drawing of the C-MOS inverter according to the first embodiment of the present invention. As illustrated in FIG. 2(a), wiring 1 is provided for making connection between a source region Sp of the p-MOS transistor and the power supply VDD. Also provided is wiring 2 for making connection between a drain region Dp of p-MOS transistor and a drain region Dn of the n-MOS transistor. On the other hand, wiring 3 is connected at one end to a source region Sn of the n-MOS transistor while the other end is returned to ground. For example, aluminum (Al) wiring is used for the wirings 1˜3.

The input signal A as shown in FIGS. 1(a), (b) and FIG. 2(a) is applied to a gate line G in FIG. 2(a). On the other hand, an output signal F is derived from the wiring 2 in FIG. 2(a).

According to the layout in this particular embodiment of the semiconductor device, the p-MOS and n-MOS transistors are fabricated in such a manner that their impurity diffused regions contact to each other, thereby eliminating the need for separation width between the p-MOS and n-MOS transistors and contributing to reduce the layout area. Additionally, no upper layer connection between the p-MOS and n-MOS transistors is required, thereby reducing wiring capacitance and providing a margin for upper layer wiring in the layout. It is unnecessary to implant impurity ion at the junction of the impurity diffused regions of both the p-MOS and n-MOS transistors. Alternatively, it is possible that opposite conductivity type impurities are ion implanted.

It is to be noted that a gate width WGp of the p-MOS transistor is made wider than a WGn of the n-MOS transistor as illustrated in FIG. 2(a). Since carrier mobility is different in the p-MOS and n-MOS transistors, the n-MOS transistor flows larger current than the p-MOS transistor if the gate width of both the p-MOS and n-MOS transistors is equalized. The above design compensates for currents of the p-MOS and n-MOS transistors.

Now, illustrated in FIG. 2(b) is a cross section view along the line X-X′ in FIG. 2(a). As apparent from FIG. 2(b), a SOI substrate comprises a silicon layer formed on a silicon substrate 11 by way of a buried oxide film 12. A device isolation region 14, e.g., STI or the like is formed on the buried oxide film 12 in such a manner to surround the silicon layer. Alternatively, the device isolation region 14 may be made by LOCOS or mesa rather than STI. Devices are isolated by the device isolation region 14 and the buried oxide film 12 except the boundary between the p-MOS and n-MOS transistors.

Provided in the silicon layer at the p-MOS transistor portion are p-type source region 15S (Sp), p-type drain region 15D (Dp) and n-type body region 16 sandwiched between both regions 15S and 15D. Provided on the n-type body region 16 are a gate insulation film 17 and a gate electrode 18. On the other hand, provide in the silicon layer of the n-MOS transistor portion are n-type source region 19S (Sn), n-type drain region 19D (Dn) and p-type body region 20 sandwiched between both regions 19S and 19D. Provided on the p-type body region are the gate insulation film 17 and the gate electrode 18.

A high melting point metal silicide (e.g., cobalt silicide, titanium silicide, etc.) layer 21 is provided on the surface of the silicon surrounded by the device isolation region 14 and the gate electrode 18 for connecting the drain region 15D of the p-MOS transistor and the drain region 19D of the n-MOS transistor by way of the high melting point metal silicide, thereby maintaining the drain regions 15D and 19D to the same potential.

Prior to forming the high melting point silicide layer 21, side-walls (SW) 30 of an insulation film are formed on the side surfaces of the gate electrodes 18 to prevent siliciding the side surfaces of the gate electrodes. Accordingly, the side-walls 30 prevent short-circuiting the source/drain regions 15S, 15D, 19S, 19D and the gate electrodes 18 by way of the silicide on the side surfaces of the gate electrodes 18. In this case, the thickness of the side-walls 30 may be thinner than side-walls for making LDD structure. An insulation film 22 of, e.g., a silicon oxide film is formed on the high melting point metal silicide layer 21 or the gate electrodes 18. Also provided on the insulation film 22 are the wiring 1 for connecting the source region 15S of the p-MOS transistor to the power supply, the wiring 2 for supplying an output signal of the C-MOS inverter and the wiring 3 for connecting the source region 19S of the n-MOS transistor to ground.

A source contact (SCp) 23 is provided in the insulation film 22 immediately below the wiring 1. A drain contact (DC) 24 is provided in the insulation film 22 immediately below the wiring 2. Also provided in the insulation film 22 immediately below the wiring 3 is a source contact (SCn). Although not shown in FIG. 2(b), a gate contact GC is provided on the gate line G as shown in FIG. 2(a).

Now, the method of fabricating the semiconductor device according to the present invention will be described hereunder.

A first step is to form the device isolation region (I) 14 on the surface of the SOI substrate as shown in FIGS. 3(a), (b). That is, the silicon layer 13 is formed on the silicon substrate 11 by way of the buried oxide film 12. Subsequently, the device isolation region 14 is formed on the buried oxide film 12 by, e.g., STI process.

The SOI substrate may be fabricated by, e.g., SIMOX (Separation by IMplanted OXygen) process or sticking process. The SIMOX process is to implant oxygen ion into the silicon substrate by applying high energy before performing high temperature heat treatment for forming a silicon oxide film (buried oxide film) inside the silicon substrate. On the other hand, the sticking process is to stick two substrates and polishing the surface. Generally, the SIMOX process is effective to provide thinner and more uniform thickness silicon layer as compared to the sticking process.

A next step is to apply a resist (R) 26 on the SOI substrate acting as a mask for impurity ion implantation in p-MOS transistor portion as shown in FIGS. 4(a), (b). In consideration of alignment margin in the photolithography process, an opening in the resist 26 is set slightly larger than the active area of the p-MOS transistor surrounded by the device isolation region (I) 14. However, the edge of the opening in the resist 26 is aligned with the boundary of the p-MOS and the n-MOS transistors. N-type impurity ions are implanted using the resist 26 as a mask for forming the n-type body region 16. Then, the resist 26 is removed.

Subsequently, a resist (R) 27 acting as a mask for impurity ion implantation in the n-MOS transistor portion is applied on the SOI substrate as shown in FIGS. 5(a), (b). It is to be noted that an opening in the resist 27 is set slightly larger than the active region of the n-MOS transistor surrounded by the device isolation region (I) 14 in consideration of alignment margin in the photolithography process. However, the edge of the resist 27 is aligned with the boundary of the p-MOS and the n-MOS transistors. The p-type body region 20 is formed by implanting p-type impurity ions through the resist 27 acting as a mask. Then, the resist 27 is removed.

Subsequently, the gate electrodes (G) 18 are formed on the SOI substrate by way of the gate insulation film 17 as shown in FIGS. 6(a), (b). The gate insulation film 17 may be, e.g., a thermal oxide film formed on the surfaces of the n-type body region 16 and the p-type body region 20. The gate electrodes 18 may be formed by, e.g., a chemical vapor deposition (CVD) of non-doped poly-silicon layer not containing impurities. Then, the gate electrodes 18 and the gate insulation film 17 are formed by performing, e.g., reactive ion etching (RIE) through the resist as a mask.

Subsequently, a resist (R) 28 is applied to act as a mask for implanting impurity ions into the p-MOS transistor portion as shown in FIGS. 7(a), (b). It is to be noted that an opening in the resist 28 is set larger than the n-type body region 16 in consideration of the alignment margin in the photolithography process. However, the edge of the opening in the resist 28 is aligned with the boundary of the p-MOS and n-MOS transistors. P-type impurity ions are implanted into the n-type body region 16 using the resist 28 and the gate electrodes 18 as a mask. Accordingly, the p-type source region (Sp) 15S and the p-type drain region (Dp) 15D self-aligned with respect to the gate electrodes 18 are formed. Then, the resist 28 is removed.

Subsequently, a resist (R) 29 is applied to act as a mask for implanting impurity ion into the n-MOS transistor portion as shown in FIGS. 8(a), (b). It is to be noted that an opening in the resist 29 is set to be larger than the p-type body region 20 in consideration of the alignment margin in the photolithography process. However, the edge of the opening is aligned with the boundary of the p-MOS and n-MOS transistors. P-type impurity ions are implanted through the resist 29 and the gate electrodes 18 acting as a mask to form the n-type source region (Sn) 19S and the n-type drain region (Dn) 19D in a self-aligned manner with respect to the gate electrodes 18. Then, the resist 29 is removed.

Subsequently, side-walls (SW) 30 are formed on the side surfaces of the gate electrodes 18 as shown in FIGS. 9(a), (b). In order to form the side-walls 30, an insulation film such as silicon oxide film provided by the CVD process on the entire surface is first formed and then etched back. Subsequently, a high melting point metal silicide layer 21 is formed on the source/drain regions 15S, 15D, 19S, 19D and the gate electrodes 18 of the p-MOS and n-MOS transistors. It is to be noted that the side-walls 30 may be formed before forming the p-type source/drain regions (Sp) 15S, (Dp) 15D and n-type source/drain regions (Sd) 19S, (Dn) 19D. In this particular case, the side-walls 30 are made relatively thin for forming the source/drain regions in a self-aligned manner with respect to the side-walls 30. The ion-implanted impurities may be diffused in the body regions below the side-walls 30 by thermal treatment.

In order to form the high melting point silicide layer 21, the silicon layer or a natural oxide film on the surface of the gate electrodes are removed by light etching process using, e.g., fluoric acid. Subsequently, for example, cobalt is deposited to the thickness of about 10 nm by sputtering. Silicide is, then, formed on the silicon surface by, e.g., rapid thermal annealing (RTA). Non-reacted cobalt on the silicon oxide film is removed using, e.g., a solution containing sulfuric acid and hydrogen peroxide.

Subsequently, an insulation film 22 such as, e.g., silicon oxide film is deposited on the entire surface by the CVD as shown in FIG. 2. Contact holes are bored in the insulation film 22 by performing, e.g., the RIE through a resist acting as a mask. For example, tungsten is buried in the contact holes and then upper layer wirings 1˜3 are provided for making plug connection with the tungsten, thereby forming source contacts 23, 25, drain contact 24 and gate contact to complete the semiconductor device according to the present invention.

(Second Embodiment)

The semiconductor device according to the second embodiment of the present invention is designed to improve withstanding voltage by applying the LDD structure to the C-MOS transistors in the first embodiment of the present invention. The C-MOS inverter in this particular embodiment is identical to the first embodiment in the logic symbol and circuit schematic as shown in FIGS. 1(a), (b) and its truth table is represented by the above Table 3.

FIG. 10(a) is a layout drawing of the second embodiment of the C-MOS inverter, and FIG. 10(b) is a cross section view along the line X-X′ in FIG. 10(a). As shown in FIGS. 10(a), (b), side-walls (SW) 31 of an insulation film such as silicon oxide or the like are provided on the side surfaces of the gate electrodes 18. P-type LDD region 32 containing lower p-type impurity than the p-type source/drain regions 15S, 15D is formed below the side-wall 31 of the p-MOS transistor. On the other hand, an n-type LDD region 33 containing lower n-type impurity than the n-type source/drain regions 19S, 19D is formed below the side-wall 31 of the n-MOS transistor.

According to the second embodiment of the C-MOS inverter, the p-MOS and n-MOS impurity diffusion regions are formed to contact each other in the same manner as the first embodiment inverter, thereby eliminating the separation width between the p-MOS and n-MOS transistors and reducing the layout area. Also, upper layer wirings for interconnecting the p-MOS and n-MOS transistors are eliminated, thereby reducing wiring capacitance and providing a margin in layout for the upper layer wirings.

It is unnecessary to implant impurity ions into the junction portion between the p-MOS and n-MOS impurity diffused regions or impurity ions of opposite conductivity types may be implanted. Also, the gate width of the p-MOS transistor is increased in order to compensate currents due to different carrier mobility of the p-MOS and n-MOS transistors.

As shown in FIG. 10(b), the high melting point metal silicide layer 21 such as, e.g., cobalt silicide, titanium silicide, etc. is formed on the surface of p-type source/drain regions 15S, 15D and the surface of n-type source/drain regions 19S, 19D and on the gate electrodes 18. In this manner, the drain region of the p-MOS transistor and the drain region of the n-MOS transistor are connected together by way of the high melting point metal suicide layer 21, thereby maintaining both drain regions at the same potential. Also, formation of the side-walls 31 on the side surfaces of the gate electrodes 18 prevents short-circuiting the high melting point metal silicide layer 21 on the gate electrodes 18 and the high melting point metal silicide layer 21 on the source/drain regions 15S, 15D, 19S, 19D.

It is to be noted that the high melting point metal silicide layer 21 on the gate electrodes 18 is unnecessary in the second embodiment of the C-MOS inverter. However, such high melting point metal silicide layer on the gate electrodes 18 helps to reduce resistance of the gate electrodes 18.

Now, the method of fabricating the second embodiment of semiconductor device will be described. In FIGS. 11(a), (b)˜FIGS. 16, (a) and (b) are respectively layout drawings and cross section views along the line X-X′ in FIGS. 11(a) FIGS. 16(a) similar to FIGS. 10(a), (b).

The method of fabricating the second embodiment of the semiconductor device is the same as that of the first embodiment in the steps as shown in FIGS. 3(a), (b) FIGS. 6(a), (b). As shown in FIGS. 6(a), (b), the n-type body region 16 and the p-type body region 20 are formed respectively on the p-type MOS and n-type MOS transistor portions for forming the gate electrodes 18 in the same manner as the first embodiment. Subsequently, a resist (R) 34 is applied in the p-MOS transistor portion as a mask in impurity ion implantation as shown in FIGS. 11(a), (b). It is to be noted that an opening in the resist 34 is set to be larger than the n-type body region 16 in consideration of the alignment margin in the photolithography process. However, the edge of the opening is aligned with the boundary portion of the p-MOS and n-MOS transistors. Then, p-type impurity ions are implanted into the n-type body region 16 through a mask of the resist 34 and the gate electrode 18, thereby forming the p-type LDD region 32 in a self-aligned manner with respect to the gate electrode 18. The resist 34 is, then, removed.

Subsequently, applied is the resist (R) 35 acting as a mask for implanting impurity ions into the n-MOS transistor portion as shown in FIGS. 12(a), (b). It is to be noted that an opening in the resist 35 is set to be larger than the p-type body portion in consideration of the alignment margin in the photolithography process. However, the edge of the opening of the resist 35 is aligned with the boundary of the p-MOS and n-MOS transistors. Subsequently, n-type impurity ions are implanted into the p-type body region 20 through a mask of the resist 35 and the gate electrode 18 for forming the n-type LDD region 33 in the self-aligned manner with respect to the gate electrode 18. Then, the resist 35 is removed.

Subsequently, the side-walls (SW) 31 are formed on the side surfaces of the gate electrodes 18 as shown in FIGS. 13(a), (b). The side-walls 31 are formed by first forming an insulation film such as, e.g., a silicon oxide film by the CVD over the entire surface before performing etch back. Then, applied is a resist (R) 36 acting as a mask for implanting impurity ions into the p-MOS transistor portion as shown in FIGS. 14(a), (b). it is to be noted that an opening in the resist 36 is set to be larger than the n-type body region 16 in consideration of the alignment margin in the photolithography process. However, the edge of the opening in the resist 36 is aligned with the boundary of the p-MOS and n-MOS transistors. Subsequently, p-type impurity ions are implanted into the n-type body region 16 through the resist 36 and the side-walls 31 on the side surface of the gate electrode 18, thereby forming the p-type source region (Sp) 15S and the p-type drain region (Dp) 15D of higher p-type impurity concentration than the p-type LDD region 32. Then, the resist 36 is removed.

Subsequently, applied is a resist (R) 37 acting as a mask in the impurity ion implantation into the n-MOS transistor portion as shown in FIGS. 15(a), (b). It is to be noted that an opening in the resist 37 is set to be larger than the p-type body region 20 in consideration of the alignment margin in the photolithography process. However, the edge of the opening in the resist 37 is aligned with the boundary of the p-MOS and n-MOS transistors. N-type impurity ions are implanted into the p-type body region 20 through a mask of the resist 37 and the side-walls 31 on the side surfaces of the gate electrode 18, thereby forming n-type source region (Sn) 19S and n-type drain region (Dn) 19D of lower n-type impurity concentration than then-type LDD region 33. Then, the resist 37 is removed.

Subsequently, a high melting point metal silicide layer 21 is formed on the source/drain regions 15S, 15D, 19S, 19D and the gate electrodes 18 of the p-MOS and n-MOS transistors as shown in FIGS. 16(a), (b). The insulation film 22 is, then, formed by depositing, e.g., a silicon oxide film by CVD over the entire surface as shown in FIGS. 10(a), (b). Contact holes are bored in the insulation film 22 by, e.g., a RIE process using a masking resist. For example, tungsten is buried in the contact holes and the upper layer wirings 1˜3 are formed for connection with the tungsten plugs, thereby forming the source contacts 23, 25, the drain contact 24 and the gate contact. The second embodiment of the semiconductor device is completed by the above steps.

(Third Embodiment)

A 2-input NAND gate is shown as an example of circuits fabricated on a SOI substrate. FIG. 17(a) shows a logic symbol of such 2-input NAND gate and FIG. 17(b) shows a circuit schematic of the 2-input NAND gate. FIG. 18 shows a layout drawing of the 2-input NAND gate. A truth table of the 2-input NAND gate is given in the following Table 4:

TABLE 4

| input A | input B | output F |
|---|---|---|
| 1 | 1 | 0 |
| 1 | 0 | 1 |
| 0 | 1 | 1 |
| 0 | 0 | 1 |

As shown in FIG. 17(b), a pair of p-MOS transistors are connected in parallel and a pair of n-MOS transistors are connected in series. The sources of the p-MOS transistors are clamped to the power supply voltage VDD, while the drains of the p-MOS transistors define the output terminal. The sources of the n-MOS transistors are connected to ground while the drain of one n-MOS transistor defines the output terminal.

As shown in FIG. 18, wiring 41 is connected between the source region Sp of the p-MOS transistor and the power supply VDD, wiring 42 is connected between the drain region Dp of the p-MOS transistor and the drain region Dn of the n-MOS transistor and wiring 43 is connected to the source region Sn of one n-MOS transistor at its one end and to ground at the other end. For example, aluminum (Al) wiring is used as the wirings 41 43. The source region Sp of the p-MOS transistor and the wiring 41 are connected by way of source contact SCp. The drain region Dp of the p-MOS transistor and the drain region Dn of the n-MOS transistor are connected to the wiring 42 by way of drain contact DC. The source region Sn of n-MOS transistor and the wiring 43 are connected by way of source contact SCn.

As shown in FIGS. 17(b) and FIG. 18, the input signal A is applied to gate electrodes GA of one each of the p-MOS and n-MOS transistors while the input signal B is applied to gate electrodes GB of the other p-MOS and n-MOS transistors. The output signal F as shown in FIG. 17 is derived from the wiring 42 in FIG. 18.

According to the layout of the third embodiment of the semiconductor device, the p-MOS and n-MOS transistors are fabricated in such a manner that their impurity diffused regions contact to each other, thereby eliminating the separation width between the p-MOS and n-MOS transistors and reducing the layout area. Also, there is no need for upper layer wiring for connecting the p-MOS and n-MOS transistors, thereby reducing wiring capacitance and creating a margin for the upper layer wiring layout.

There is no need for implanting impurity ions into the contacting area of the impurity diffused regions of the p-MOS and n-MOS transistors. Alternatively, opposite conductivity type ions may be implanted. Represented by Rp in FIG. 18 is a resist pattern to be used as a mask in impurity ion implantation in the p-MOS transistor portion. This resist pattern is used in forming the p-type source/drain regions 15S, 15D similar to the resist 28 in FIG. 7(b). On the other hand, represented by Rn in FIG. 18 is a resist pattern to be used as a mask in impurity ion implantation in the n-MOS transistor portion. This resist pattern is used for forming the n-type source/drain regions 19S, 19D similar to the resist 29 in FIG. 8(b). Like the C-MOS inverter of the first embodiment, the gate width WGp of the p-MOS transistor is made larger than the gate width Wgn of the n-MOS transistor in order to compensate currents of the p-MOS and n-MOS transistors due to different carrier mobility. Although not shown in FIG. 18, side-walls may be provided, if necessary, on the side surfaces of the gate electrodes GA, GB similar to the first embodiment of the semiconductor device.

Illustrated in FIG. 19 is a cross section view along the line X-X′ in FIG. 18. A silicon layer is formed on the silicon substrate 11 by way of the buried oxide film 12 to define the SOI substrate as shown in FIG. 19. A device isolation region (I) 14 is formed in the silicon layer by, e.g., the STI or other process. The device isolation region 14 may be made by the LOCOS process rather than the STI. The device isolation region 14 reaches the buried oxide film 12, thereby isolating devices by the device isolation regions 14 and the buried oxide film 12 except the boundary portion of p-MOS and n-MOS transistors.

Formed in the silicon layer in the p-MOS transistor portion are p-type source region (Sp) 15S, p-type drain region (Dp) 15D and n-type body region 16 sandwiched between these regions 15S and 15D. The gate insulation film 17 and the gate electrodes 18 are formed on the n-type body regions 16 to fabricate a pair of parallel connected p-MOS transistors.

On the other hand, formed in the silicon layer in the n-MOS portion are n-type source regions (Sn) 19S, n-type drain regions (Dn) 19D and p-type body regions 20 sandwiched between these regions 19S and 19D. Gate insulation film 17 and gate electrodes are formed on the p-type body regions 20 to fabricate a pair of series connected n-MOS transistors.

A high melting point metal suicide layer 21 such as, e.g., cobalt silicide, titanium silicide, etc. is formed on the surface of the silicon layer surrounded by the device isolation region 14 and the gate electrodes 18 for connecting the drain regions 15D of the p-MOS transistors and the drain regions 19D of the n-MOS transistors for maintaining at the same potential. Prior to forming the high melting point silicide layer 21, siliciding of the side surfaces of the gate electrodes 18 is effectively prevented by forming the side-walls (SW) 30 on the side surfaces of the gate electrodes 18, thereby preventing the source/drain regions 15S, 15D, 19S, 19D from short-circuiting the gate electrodes 18 by way of the silicide on the side surfaces of the gate electrodes 18. In this case, the thickness of the side-walls 30 may be thinner than the side-walls in the LDD structure.

Formed on the high melting point silicide layer 21 or the gate electrodes 18 is an insulation film 22 of, e.g., silicon oxide. Formed on the insulation film 22 are the wiring 42 from which the output signal of the 2-input NAND gate is derived and the wiring 43 for connecting the source region of the n-MOS transistor to ground. Drain contacts (DCp, DC) 24 are formed in the insulation film 22 immediately below the wiring 42. Also, source contact (SCn) 25 is formed in the insulation film 22 immediately below the wiring 43.

The method of fabricating the 2-input NAND gate is similar to that of the first embodiment C-MOS inverter but is modified in the layout design.

It is possible to fabricate in the LDD structure similar to the second embodiment of the C-MOS inverter by forming the side-walls (SW) of an insulation film on the side surfaces of the gate electrodes as shown in FIG. 20. FIG. 21 is a cross section view along the line X-X′ in FIG. 20. In the case of the LDD structure, drain regions of the p-MOS transistors and drain regions of the n-MOS transistors are connected by the high melting point metal silicide layer 21 and maintained at the same potential. Although it is unnecessary to form the high melting point metal silicide layer on the gate electrodes 18, such high melting point metal silicide layer 21 helps to reduce resistance of the gate electrodes 18.

Represented by Rp in FIG. 20 is a resist pattern to be used as a mask in impurity ion implantation in the p-MOS transistor portion. Such resist pattern is used for forming the p-type LDD region 32 and the p-type source/drain regions 15S, 15D similar to the resist 34 in FIG. 11(a) or the resist 36 in FIG. 14(a). On the other hand, represented by Rn in FIG. 20 is a resist pattern to be used in impurity ion implantation in the n-MOS transistor portion. Such resist pattern is used for forming the n-type LDD region 33 and the n-type source/drain regions 19S, 19D similar to the resist 35 in FIG. 12(a) and the resist 37 in FIG. 15(a).

According to the third embodiment of semiconductor device, separation width between the p-MOS and n-MOS transistors in the C-MOS transistors to be fabricated on a SOI substrate can be eliminated, thereby reducing the necessary layout area. Additionally, in the semiconductor device according to the present invention, the upper layer wiring for the interconnecting p-MOS and n-MOS transistors (e.g., the wiring 82 between DCn, DCp in the conventional semiconductor device in FIG. 24 and the wiring 92 between DCn, DCp in the conventional semiconductor device in FIG. 25) can be eliminated, thereby reducing the wiring capacitance. Elimination of the resistance in this portion between the power supply VDD and ground GND contributes high-speed operation and also creates a margin in wiring layout.

Embodiments of the semiconductor device and the method of fabricating the semiconductor device according to the present invention are not limited to only those described herein-above. For example, the present invention is applicable to the C-MOS circuits constituting NOR gates. Various other modifications may be made without departing from the subject matter of the present invention.

As understood from the above descriptions, the semiconductor device according to the present invention makes it possible to reduce layout area of the C-MOS transistors fabricated on a SOI substrate, thereby providing highly integrated semiconductor devices. Also, the method of fabricating semiconductor device according to the present invention can provide highly integrated C-MOS transistors on a SOI substrate.

What is claimed is:

1. A semiconductor device comprising:
a substrate;
a buried insulation film formed on the substrate;
a semiconductor layer formed on the buried insulation layer;
a device isolation region formed on the buried insulation film in such a manner to surround said semiconductor layer;
a plurality of first conductivity type impurity diffused regions formed in said semiconductor layer;
a second conductivity type body region formed in said semiconductor layer between said first conductivity type impurity diffused regions;
a plurality of second conductivity type impurity diffused regions formed in said semiconductor layer;
a first conductivity type body region formed in said semiconductor layer between said second conductivity type impurity diffused regions;
a junction surface of one of said first conductivity type impurity diffused regions and one of said second conductivity type impurity diffused regions;
a conductive layer formed on at least one of said first conductivity type impurity diffused regions and one of said second conductivity type impurity diffused regions including said junction surface;
a gate insulation film formed on said first conductivity type body region and said second conductivity type body region; and gate electrodes formed on said gate insulation film.

2. The semiconductor device of claim 1, wherein
said semiconductor layer contains silicon, and
said conductive layer contains a metal silicide layer.

3. The semiconductor device of claim 1, further comprising:
a first wiring for connecting one of said first conductivity type impurity diffused regions not contacting the second conductivity type impurity diffused regions and a power supply; and
a second wiring for connecting one of said second conductivity type impurity diffused regions not contacting said first conductivity type impurity diffused regions to ground.

4. The semiconductor device of claim 3, further comprising:
a pair of said first conductivity type impurity diffused regions; and
a pair of said second conductivity type impurity diffused regions.

5. The semiconductor device of claim 3, further comprising:
3 of said first conductivity type impurity diffused regions; and
3 of said second conductivity type impurity diffused regions, wherein
said gate electrodes include a first gate electrode formed on said one first conductivity type body region and said one second conductivity body region, and
a second gate electrode separated from said first gate electrode formed on another first conductivity type body region and another second conductivity type body region.

6. The semiconductor device of claim 1, further comprising:
a conductive layer formed on said surface of the gate electrodes.

7. The semiconductor device of claim 6, further comprising:
side-walls of an insulation film formed on the side surface of each gate electrode, wherein
said conductive layer is formed on said gate electrodes.

8. The semiconductor device of claim 1, further comprising:
side-walls of an insulation film formed on said side surface of each gate electrode,
first conductivity type LDD regions formed on the semiconductor layer at the lower portions of the side-walls and contacting the second conductivity type body region and containing lower first conductivity type impurity concentration than the first conductivity type impurity diffused regions, and
second conductivity type LDD regions formed in the lower portions of said side-walls and contacting the first conductivity type body regions and containing lower second conductivity type impurity concentration than the second conductivity type impurity diffused regions.

9. The semiconductor device of claim 8, further including:
a conductive layer formed on said gate electrodes.

10. A method of fabricating semiconductor device comprising the steps of:
forming a silicon layer on a substrate by way of a buried insulation film;
forming a device isolation insulation region on the buried insulation film surrounding the semiconductor layer;
forming a first conductivity type body region in one part of the semiconductor layer;
forming a second conductivity type body region in one part of the semiconductor layer;
forming a gate insulation film on the first and second conductivity type body regions;
forming gate electrodes on the gate insulation film;
forming a plurality of first conductivity type impurity diffused regions in the semiconductor layer by way of the second conductivity type body region;
forming a plurality of second conductivity type impurity diffused regions in the semiconductor layer by way of the first conductivity type body region in such a manner that one of the first conductivity type impurity diffused regions and one of the second conductivity type impurity diffused regions contact to define a junction surface; and
forming a conductive layer on at least one of the first conductivity type impurity diffused regions and one of the second conductivity type diffused regions including the junction surface.

11. The method of fabricating semiconductor device of claim 10, wherein
said semiconductor layer contains silicon, and
said step of forming the conductive layer includes the step of forming a metal silicide layer.

12. The method of fabricating semiconductor device of claim 10, further including the steps of:
forming an insulation film on at least the first conductivity type impurity diffused regions, the second conductivity type impurity diffused regions and the gate electrodes after forming said conductive layer;
forming a first wiring on the insulation film for connecting one of the other first conductivity type impurity diffused regions and a power supply; and
forming a second wiring on the insulation film for connecting to ground one of the other second conductivity type impurity diffused regions.

13. The method of fabricating semiconductor device of claim 10, wherein
said step of forming the first conductivity type impurity diffused regions includes the step of implanting first conductivity type impurity ions into the silicon layer using the gate electrodes as a mask, and
said step of forming the second conductivity type impurity diffused regions includes the step of implanting second conductivity type impurity ion into the semiconductor layer using the gate electrodes as a mask.

14. The method of fabricating semiconductor device of claim 10, wherein
said step of forming the conductive layer includes the step of forming the conductive layer on the surface of the gate electrodes.

15. The method of fabricating semiconductor device of claim 14, further including the step of:
forming side-walls of an insulation film on said side surface of each gate electrode, and
said step of forming the conductive layer including said step of forming the conductive layer on the gate electrodes.

16. The method of fabricating semiconductor device of claim 15, wherein
said step of forming the side-walls is carried out after forming the gate electrodes but before forming the first and second conductivity type impurity diffused regions.

17. The method of fabricating semiconductor device of claim 15, wherein
said step of forming the side-walls is carried out after forming the first and second conductivity type impurity diffused regions.

18. The method of fabricating semiconductor device of claim 10, further comprising the steps of:
forming a first conductivity type LDD regions by implanting the first conductivity type impurity ions into the semiconductor layer using the gate electrodes as a mask after forming the gate electrodes but before forming the first conductivity type impurity diffused regions;
forming second conductivity type LDD regions by implanting the second conductivity type impurity ions into the semiconductor layer using the gate electrodes as a mask after forming the gate electrodes but before forming the second conductivity type impurity diffused regions; and
forming side-walls of an insulation film on the side surface of the gate electrodes after forming said first conductivity type LDD regions and said second conductivity type LDD regions; wherein
said step of forming the first conductivity type impurity diffused regions includes the step of implanting the first conductivity type impurity ion into the semiconductor layer using the side-walls as a mask, and
said step of forming the second conductivity type impurity diffused regions includes the step of implanting the second conductivity type impurity ion into the semiconductor layer using the side-walls as a mask.

19. The method of fabricating semiconductor device of claim 18, wherein
said step of forming the conductive layer includes said step of forming the conductive layer on the gate electrodes.
